(19) United States
(12) Patent Application Publication
(10) Pub. No.: US 2026/0185240 A1
(43) Pub. Date: Jul. 2, 2026

(54) COMPOSITION, METHOD OF TREATING METAL-CONTAINING FILM AND METHOD OF MANUFACTURING ELECTRONIC DEVICE

(71) Applicants: Samsung Electronics Co., Ltd., Suwon-si (KR); Ewha University - Industry Collaboration Foundation, Seoul (KR)

(72) Inventors: Insun PARK, Suwon-si (KR); Byungkwon KIM, Seoul (KR); Jeewoo KIM, Seoul (KR); Yejin LEE, Seoul (KR); Byungjoon KANG, Suwon-si (KR); Jeongil PARK, Suwon-si (KR); Kum Hee LEE, Suwon-si (KR); Kyuyoung HWANG, Suwon-si (KR)

(73) Assignees: Samsung Electronics Co., Ltd., Suwon-si (KR); Ewha University - Industry Collaboration Foundation, Seoul (KR)

(21) Appl. No.: 19/427,420

(22) Filed: Dec. 19, 2025

(30) Foreign Application Priority Data
Dec. 27, 2024 (KR) 10-2024-0199346
Dec. 16, 2025 (KR) 10-2025-0200538

(51) Int. Cl. C23F 1/16; H10P 50/66

(52) U.S. Cl. CPC C23F 1/16; H10P 50/667

(57) ABSTRACT

Provided are a composition including an oxidizing agent, an acid, and an etching controller, a method of treating a metal-containing layer by using the same, and a method of manufacturing an electronic device by using the composition. The etching controller may include at least one of a compound represented by Formula 1 and a polymer including a repeating unit represented by Formula 2:

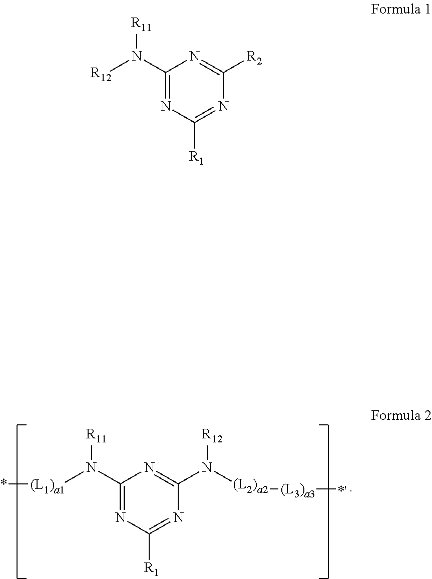

Formulae 1 and 2 are as described in this specification.

### CROSS-REFERENCE TO RELATED APPLICATION

This application is based on and claims priority under 35 U.S.C. § 119 to Korean Patent Applications Nos. 10⁻²⁰²⁴-0199346, filed on Dec. 27, 2024 and 10⁻²⁰²⁵-0200538, filed on Dec. 16, 2025, in the Korean Intellectual Property Office, the disclosure of which is incorporated by reference herein in its entirety.

### BACKGROUND

### 1. Field

The disclosure relates to a composition, a method of treating a metal-containing film by using the same and a method of manufacturing an electronic device by using the composition.

### 2. Description of the Related Art

To meet consumer demands for excellent performance and affordable prices, an increase in semiconductor device integration and an improvement in reliability may be advantageous. As the degree of integration of semiconductor devices increases, damage to components of semiconductor devices during the manufacturing process may have more influence on reliability and electrical characteristics of semiconductor memory devices. In particular, during the semiconductor device manufacturing process, various treatment processes, such as etching, cleaning, and polishing processes, may be performed on a given film (e.g., a metal-containing film), and a composition having an appropriate etching rate may be advantageous to perform a more effective treatment processes on metal-containing films.

### SUMMARY

Provided are a composition capable of more effectively controlling the etching rate for various metal-containing films, a method of treating a metal-containing film by using the composition, and a method of manufacturing an electronic device by using the composition.

Additional aspects will be set forth in part in the description which follows and, in part, will be apparent from the description, or may be learned by practice of the presented embodiments of the disclosure.

According to an aspect of the disclosure, a composition may include
an oxidizing agent, an acid, and an etching controller, wherein
the etching controller may include at least one of a compound represented by Formula 1 and a polymer including a repeating unit represented by Formula 2.

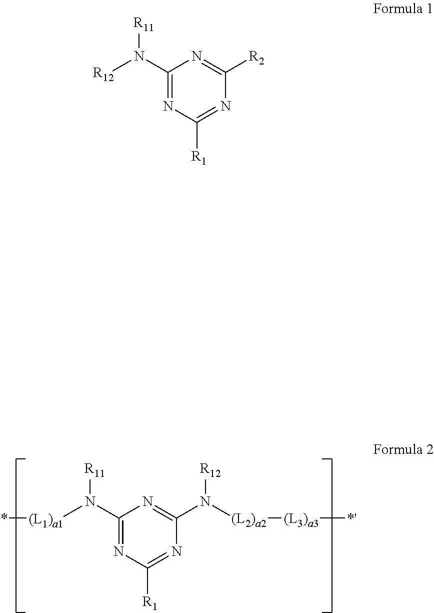

wherein, in Formulae 1 and 2,
R₁ and R₂ may each independently be
hydrogen, a halogen atom, *—OH, *—SH, or *—C(═O)OH,
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof, or

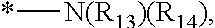

R₁₁ to R₁₄ may each independently be
hydrogen, a halogen atom, *—OH, *—SH, or *—C(═O)OH, or
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
L₁ to L₃ may each independently be
a single bond, O, or S, or
a C₁-C₃₀ alkylene group, a C₂-C₃₀ alkenylene group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
a1 to a3 may each independently be an integer from 1 to 30, and
* and *′ each indicate a binding site to a neighboring atom.

According to another aspect of the disclosure, a method of treating a metal-containing film may include
preparing a substrate including the metal-containing film, the metal-containing film including a first region and a second region; and
contacting the metal-containing film with the composition;
wherein the first region and the second region independently may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof,
wherein a material included in the first region may be different from a material included in the second region.

According to another aspect of the disclosure, a method of manufacturing an electronic device including a transistor is provided. The transistor may include a channel; a source and a drain spaced apart from each other and electrically connected to the channel; a gate electrode; and a gate insulating film between the gate electrode and the channel, and the method may include:
providing a barrier layer comprising a metal nitride, a metal oxynitride, or any combination thereof;
providing a conductive layer including a conductive metal; and
forming the gate electrode by bringing the barrier layer and the conductive layer into contact with the composition to etch a portion of the barrier layer and a portion of the conductive layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 2 are schematic views briefly illustrating an embodiment of a method of treating a metal-containing film;

FIG. 1B is a schematic view showing the surface of a metal-containing film (20A) of FIG. 1A that may be brought into contact with a composition (30);

FIGS. 3 and 4 are schematic views briefly illustrating other embodiments of a method of treating a metal-containing film;

FIG. 5 is a schematic plan view of an electronic device according to an embodiment;

FIG. 6A is a perspective view of an embodiment of the electronic device illustrated in FIG. 5;

FIG. 6B is a perspective view of another embodiment of the electronic device shown in FIG. 5;

FIGS. 7 to 9 are schematic views briefly illustrating parts of a process of manufacturing the transistor structure shown in FIG. 6A; and

FIG. 10 is a process flowchart of an embodiment of a method of manufacturing an electronic device.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

### Metal-Containing Film

The metal-containing film may include an alkali metal (for example, sodium (Na), potassium (K), rubidium (Rb), cesium (Cs), or the like), an alkaline earth metal (for example, beryllium (Be), magnesium (Mg), calcium (Ca), strontium (Sr), barium (Ba), or the like), a lanthanide metal (for example, lanthanum (La), europium (Eu), terbium (Tb), ytterbium (Yb), or the like), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), or the like), post-transition metals (for example, aluminum (Al), gallium (Ga), indium (In), thallium (Tl), tin (Sn), bismuth (Bi), or the like), or any combination thereof.

According to an embodiment, the metal-containing film may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof.

According to another embodiment, the metal-containing film may include two or more different types of metals.

According to another embodiment, the metal-containing film may include titanium.

According to another embodiment, the metal-containing film may i) include titanium (Ti), and ii) optionally further include, in addition to titanium, indium (In), aluminum (Al), lanthanum (La), scandium (Sc), gallium (Ga), tungsten (W), molybdenum (Mo), ruthenium (Ru), zinc (Zn), hafnium (Hf), silicon (Si), or any combination thereof.

The metal-containing film may include a metal, a metal nitride, a metal oxide, a metal oxynitride or any combination thereof.

According to an embodiment, the metal-containing film may include a metal, a metal nitride, a metal oxide, a metal oxynitride, or any combination thereof, and each of the metal, the metal of the metal nitride, the metal of the metal oxide, and the metal of the metal oxynitride may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof.

According to another embodiment, the metal-containing film may include a metal nitride, a metal oxynitride, or any combination thereof as described above (for example, a titanium nitride, a titanium oxynitride, or any combination thereof, or the like).

According to another embodiment, the metal-containing film may include a metal as described above (for example, a conductive metal such as tungsten, molybdenum, and ruthenium).

According to another embodiment, the metal-containing film may include i) a metal nitride, a metal oxynitride, or any combination thereof as described above (for example, a titanium nitride, a titanium oxynitride, or any combination thereof, or the like) and ii) a metal as described above (for example, a conductive metal such as tungsten, molybdenum, and ruthenium).

According to another embodiment, the metal-containing film may include a titanium nitride, a titanium oxynitride, or any combination thereof, and may further include tungsten, molybdenum, ruthenium, or any combination thereof, in addition to the titanium nitride, the titanium oxynitride, or any combination thereof. Each of the titanium nitride and titanium oxynitride may optionally further include indium, aluminum, lanthanum, scandium, gallium, silicon, or any combination thereof.

According to another embodiment, the metal-containing film may include a titanium nitride, a titanium nitride further including aluminum (for example, TiAlN), a titanium nitride further including lanthanum, a titanium nitride further including silicon (for example, TiSiN), or the like.

The metal-containing film may be a single-layer structure including one or more types of materials or a multi-layer structure including different materials. The plurality of the films included in the multilayer structure may be vertically stacked or horizontally arranged with respect to the substrate. The single-layer structure and the multi-layer structure may have various three-dimensional patterns (for example, via holes, trenches, or the like).

According to an embodiment, the metal-containing film includes a first region and a second region, wherein the first region and the second region independently may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof, and the material included in the first region may be different from the material included in the second region.

According to another embodiment, the first region may include titanium.

According to another embodiment, the first region may i) include titanium (Ti), and ii) in addition to titanium, optionally may further include indium (In), aluminum (Al), lanthanum (La), scandium (Sc), gallium (Ga), tungsten (W), molybdenum (Mo), ruthenium (Ru), zinc (Zn), hafnium (Hf), silicon (Si), or any combination thereof.

According to another embodiment, the second region may include tungsten (W), molybdenum (Mo), ruthenium (Ru), or any combination thereof.

According to another embodiment, the first region may include titanium (Ti), indium (In), aluminum (Al), lanthanum (La), scandium (Sc), gallium (Ga), or any combination thereof, and the second region may include tungsten (W), molybdenum (Mo), ruthenium (Ru), or any combination thereof.

According to another embodiment, the first region may include a metal nitride, a metal oxynitride, or any combination thereof, and the second region may include a conductive metal.

For example, the first region may have i) a single-layer structure of a metal nitride film, ii) a single-layer structure of a metal oxynitride film, or iii) a double-layer structure of a metal nitride film and a metal oxynitride film.

According to another embodiment, the first region may include a titanium nitride, a titanium oxynitride, or any combination thereof, wherein each of the titanium nitride and the titanium oxynitride may optionally further include indium (In), aluminum (Al), lanthanum (La), scandium (Sc), gallium (Ga), silicon (Si), or any combination thereof.

According to another embodiment, the first region may include a titanium nitride, a titanium nitride further including aluminum (for example, TiAlN), a titanium nitride further including lanthanum, a titanium nitride further including silicon (for example, TiSiN), and the like.

As used herein, the etching of any film may refer to that at least a portion of the material constituting the film is removed.

### Composition

The composition may include an oxidizing agent, an acid, and an etching controller.

The composition may be used in various treatment processes for the metal-containing film described herein, for example, an etching process, a cleaning process, a polishing process, or the like.

The composition may further include water.

According to an embodiment, the composition may not substantially contain a fluorine-containing compound. Although not intended to be limited by a specific theory, when the composition includes a fluorine-containing compound and the metal-containing film is treated by using the same, adjacent materials, such as various oxides, disposed adjacent to the metal-containing film as described below may be damaged, resulting in a deterioration in the performance of electronic devices and/or semiconductor devices. In some embodiments, the composition may include the fluorine-containing compound and an amount of the fluorine-containing compound may be an amount that does not materially affect the basic characteristics of the composition (e.g., based on 100 wt % of the composition, about 10⁻² wt % or less, about 10⁻³ wt % or less, about 10⁻⁴ wt % or less, about 10⁻⁷ wt % to about 10⁻² wt %, about 10⁻⁶ wt % to about 10⁻² wt %, about 10⁻⁵ wt % to about 10⁻² wt %, about 10⁻⁷ wt % to about 10⁻³ wt %, about 10⁻⁶ wt % to about 10⁻³ wt %, or about 10⁻⁵ wt % to about 10⁻³ wt %, etc.). In some embodiments, the composition may not include the fluorine-containing compound. For example, the amount of the fluorine-containing compound in the composition may be 0 wt %. The fluorine-containing compound refers to any compound that is dissociable in an aqueous solvent while containing F, and an example thereof includes HF, NH₄F or the like.

According to an embodiment, the composition may include an oxidizing agent, an acid, an etching controller, and water.

### Oxidizing Agent

The oxidizing agent may etch at least a portion of the metal-containing film and may include a hydrogen peroxide, an iodine-containing compound, a nitric acid, an ammonium sulfate, or a combination thereof.

In an embodiment, the oxidizing agent may include a hydrogen peroxide, a periodic acid, an iodic acid, a nitric acid, an ammonium sulfate, or any combination thereof.

In another embodiment, the oxidizing agent may include hydrogen peroxide.

In some embodiments, the oxidizing agent may be hydrogen peroxide.

In some embodiments, the composition may not substantially include a fluorine-containing compound as an oxidizing agent. Although not intended to be limited by a specific theory, when the composition includes a fluorine-containing compound as an oxidizing agent and the metal-containing film is treated by using the same, adjacent materials, such as various oxides, disposed adjacent to the metal-containing film as described below may be damaged, resulting in a deterioration in the performance of electronic devices and/or semiconductor devices.

An amount (weight) of the oxidizing agent may be, for example, based on 100 wt % of the composition, about 0.001 wt % to about 10 wt %, about 0.001 wt % to about 7 wt %, about 0.001 wt % to about 5 wt %, about 0.001 wt % to about 3 wt %, about 0.001 wt % to about 1 wt %, about 0.001 wt % to about 0.7 wt %, about 0.001 wt % to about 0.5 wt %, about 0.005 wt % to about 10 wt %, about 0.005 wt % to about 7 wt %, about 0.005 wt % to about 5 wt %, about 0.005 wt % to about 3 wt %, about 0.005 wt % to about 1 wt %, about 0.005 wt % to about 0.7 wt %, about 0.005 wt % to about 0.5 wt %, about 0.01 wt % to about 10 wt %, about 0.01 wt % to about 7 wt %, about 0.01 wt % to about 5 wt %, about 0.01 wt % to about 3 wt %, about 0.01 wt % to about 1 wt %, about 0.01 wt % to about 0.7 wt %, about 0.01 wt % to about 0.5 wt %, about 0.05 wt % to about 10 wt %, about 0.05 wt % to about 7 wt %, about 0.05 wt % to about 5 wt %, about 0.05 wt % to about 3 wt %, about 0.05 wt % to about 1 wt %, about 0.05 wt % to about 0.7 wt %, about 0.05 wt % to about 0.5 wt %, about 0.1 wt % to about 10 wt %, about 0.1 wt % to about 7 wt %, about 0.1 wt % to about 5 wt %, about 0.1 wt % to about 3 wt %, about 0.1 wt % to about 1 wt %, about 0.1 wt % to about 0.7 wt %, about 0.1 wt % to about 0.5 wt %, about 0.3 wt % to about 10 wt %, about 0.3 wt % to about 7 wt %, about 0.3 wt % to about 5 wt %, about 0.3 wt % to about 3 wt %, about 0.3 wt % to about 1 wt %, about 0.3 wt % to about 0.7 wt %, about 0.5 wt % to about 0.7 wt %, about 0.3 wt % to about 0.5 wt %, or about 0.4 wt % to about 0.6 wt %.

### Acid

The acid, together with the oxidizing agent, may control the etching rate while etching at least a portion of the metal-containing film.

The acid may be one type of acid or a mixture of two or more different acids.

The acid may include an inorganic acid, an organic acid, or any combination thereof.

In an embodiment,
i) the acid may include an inorganic acid,
ii) the acid may include an organic acid, or
iii) the acid may include an inorganic acid and an organic acid.

For example, the acid may include an inorganic acid.

In an embodiment, the inorganic acid may include a phosphoric acid, a sulfuric acid, a hydrochloric acid, or any combination thereof.

In another embodiment, the inorganic acid may include a phosphoric acid.

In some embodiments, the acid may include an organic acid.

According to an embodiment, the organic acid may include at least one of a carboxylic acid, a sulfonic acid, and a phosphonic acid.

In some embodiments, the organic acid may include a carboxylic acid. For example, the carboxylic acid may include at least one of an amine-free carboxylic acid and an amine-containing carboxylic acid. In some embodiments, the number of *—C(═O)OH contained in the carboxylic acid may be selected from an integer of 1 to 10 or 1 to 5.

In some embodiments, the organic acid may include an amine-free carboxylic acid. The term “amine-free carboxylic acid” as used herein refers to a carboxylic acid that does not include a moiety represented by *—N(R)—*′ and a moiety represented by *—N(R)(R′) (wherein R and R′ are each hydrogen or any substituent, and * and *′ are each a binding site to an adjacent atom).

In some embodiments, the organic acid may not include an amine-containing carboxylic acid. The term “amine-containing carboxylic acid” as used herein refers to a carboxylic acid containing a moiety represented by *—N(R)—*′ and/or a moiety represented by *—N(R)(R′), where R and R′ are each hydrogen or any substituent, and * and *′ are each a binding site to an adjacent atom.

In some embodiments, the organic acid may include a monocarboxylic acid, a dicarboxylic acid, a tricarboxylic acid, or any combination thereof. The number of carbon atoms contained in each of the monocarboxylic acids, dicarboxylic acids and tricarboxylic acids may be 1 to 31, 1 to 20, or 1 to 10.

In some embodiments, the organic acid may include an amine-free monocarboxylic acid, an amine-free dicarboxylic acid, an amine-free tricarboxylic acid, or any combination thereof.

In some embodiments, the organic acid may be:

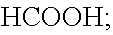

an aliphatic compound having 1 to 30 carbon atoms (e.g., 1 to 20 carbon atoms or 1 to 15 carbon atoms), or an aromatic compound having 6 to 30 carbon atoms (e.g., 6 to 15 carbon atoms or 6 to 10 carbon atoms), each substituted with at least one carboxylic acid group (*—COOH) (e.g., 1, 2 or 3 carboxylic acid groups); or
a combination thereof.

At least one hydrogen atom of the aliphatic compound and the aromatic compound may be optionally substituted with a hydroxyl group, a thiol group, a C₁-C₁₀ alkyl group (e.g., a C₁-C₅ alkyl group), a C₁-C₁₀ alkoxy group (e.g., a C₁-C₅alkoxy group), a C₁-C₁₀ alkylthio group (e.g., a C₁-C₅ alkylthio group), a phenyl group, or any combination thereof.

In some embodiments, the aliphatic compound may be a saturated aliphatic compound (e.g., an alkane, a cycloalkane, etc.) or an unsaturated aliphatic compound (e.g., an alkene, an alkyne, a cycloalkene, etc.).

In some embodiments, the aliphatic compound may be an acyclic aliphatic compound (e.g., an alkane, an alkene, an alkyne, etc.) or a cyclic aliphatic compound (e.g., a cycloalkane, a cycloalkene, an adamantane, a norborane, etc.).

In some embodiments, the aliphatic compound may be a linear aliphatic compound (e.g., CH₃—CH₂—CH₂—CH₂—CH₃, etc.) or a branched aliphatic compound (e.g., CH₃—CH(CH₃)—CH₂—CH₃, CH₃—C(CH₃)₂—CH₃, etc.).

In some embodiments, the aromatic compound may be benzene.

In some embodiments, the organic acid may include a formic acid, an acetic acid (CH₃COOH), a propionic acid, a butyric acid, a valeic acid, a lauric acid, an oxalic acid, a malonic acid, a glutaric acid, an adipic acid, a gallic acid, a succinic acid, a malic acid, a maleic acid, a crotonic acid, a fumaric acid, an ascorbic acid, a glutamic acid, a citric acid, a tartaric acid, a glycolic acid, a lactic acid, a benzoic acid, a salicylic acid, or any combination thereof.

In one or more embodiments,
i) the acid may include a phosphoric acid, or
ii) the acid may include a phosphoric acid and an amine-free carboxylic acid (e.g., an acetic acid, etc.).

In an embodiment,
i) the acid may include an inorganic acid, or
ii) the acid may include an organic acid, or
iii) the acid may include an inorganic acid and an organic acid, and wherein
the inorganic acid may include a phosphoric acid and the organic may include a carboxylic acid (e.g., acetic acid).

The amount (weight) of the acid may be, for example, based on 100 wt % of the composition, about 10 wt % to about 90 wt %, about 10 wt % to about 85 wt %, about 10 wt % to about 80 wt %, about 10 wt % to about 75 wt %, about 10 wt % to about 70 wt %, about 30 wt % to about 90 wt %, about 30 wt % to about 85 wt %, about 30 wt % to about 80 wt %, about 30 wt % to about 75 wt %, about 30 wt % to about 70 wt %, about 50 wt % to about 90 wt %, about 50 wt % to about 85 wt %, about 50 wt % to about 80 wt %, about 50 wt % to about 75 wt %, about 50 wt % to about 70 wt %, about 60 wt % to about 90 wt %, about 60 wt % to about 85 wt %, about 60 wt % to about 80 wt %, about 60 wt % to about 75 wt %, or about 60 wt % to about 70 wt %.

According to an embodiment, the acid may include an inorganic acid, and the amount (weight) of the inorganic acid may be, for example, based on 100 wt % of the composition, about 10 wt % to about 85 wt %, about 15 wt % to about 85 wt %, about 20 wt % to about 85 wt %, about 25 wt % to about 85 wt %, about 30 wt % to about 85 wt %, about 35 wt % to about 85 wt %, about 40 wt % to about 85 wt %, about 45 wt % to about 85 wt %, about 50 wt % to about 85 wt %, about 55 wt % to about 85 wt %, about 10 wt % to about 80 wt %, about 15 wt % to about 80 wt %, about 20 wt % to about 80 wt %, about 25 wt % to about 80 wt %, about 30 wt % to about 80 wt %, about 35 wt % to about 80 wt %, about 40 wt % to about 80 wt %, about 45 wt % to about 80 wt %, about 50 wt % to about 80 wt %, about 55 wt % to about 80 wt %, about 10 wt % to about 75 wt %, about 15 wt % to about 75 wt %, about 20 wt % to about 75 wt %, about 25 wt % to about 75 wt %, about 30 wt % to about 75 wt %, about 35 wt % to about 75 wt %, about 40 wt % to about 75 wt %, about 45 wt % to about 75 wt %, about 50 wt % to about 75 wt %, about 55 wt % to about 75 wt %, about 10 wt % to about 70 wt %, about 15 wt % to about 70 wt %, about 20 wt % to about 70 wt %, about 25 wt % to about 70 wt %, about 30 wt % to about 70 wt %, about 35 wt % to about 70 wt %, about 40 wt % to about 70 wt %, about 45 wt % to about 70 wt %, about 50 wt % to about 70 wt %, about 55 wt % to about 70 wt %, about 10 wt % to about 65 wt %, about 15 wt % to about 65 wt %, about 20 wt % to about 65 wt %, about 25 wt % to about 65 wt %, about 30 wt % to about 65 wt %, about 35 wt % to about 65 wt %, about 40 wt % to about 65 wt %, about 45 wt % to about 65 wt %, about 50 wt % to about 65 wt %, or about 55 wt % to about 65 wt %.

In some embodiments, the acid may include an organic acid, and the amount of the organic acid may be, based on 100 wt % of the composition, about 0.1 wt % to about 15 wt %, about 0.5 wt % to about 15 wt %, about 1 wt % to about 15 wt %, about 3 wt % to about 15 wt %, about 5 wt % to about 15 wt %, about 7 wt % to about 15 wt %, about 0.1 wt % to about 13 wt %, about 0.5 wt % to about 13 wt %, about 1 wt % to about 13 wt %, about 3 wt % to about 13 wt %, about 5 wt % to about 13 wt %, or about 7 wt % to about 13 wt %.

In some embodiments, the acid may include an organic acid and an inorganic acid, and the weight ratio of the organic acid to the inorganic acid may be in the range of 1:1 to 1:20, the range of 1:3 to 1:10, or the range of 1:5 to 1:7. For example, the acid may include an organic acid and an inorganic acid, and the weight ratio of the organic acid to the inorganic acid may be 1:6.

In some embodiments, the acid may include an inorganic acid and an organic acid, and the weight ratio of the inorganic acid to the organic acid may be in the range of 1:1 to 1:20, the range of 1:3 to 1:10, or the range of 1:5 to 1:7.

### Etching Controller

Together with the acid, the etching controller may interact with various metal atoms in the metal-containing film, which is the target film, to control the etching rate, or the like.

The etching controller may include at least one of a compound represented by Formula 1 and a polymer including a repeating unit represented by Formula 2 (i.e., (i) the compound represented by Formula 1, (ii) the polymer including a repeating unit represented by Formula 2, or (iii) the compound represented by Formula 1 and the polymer including a repeating unit represented by Formula 2):

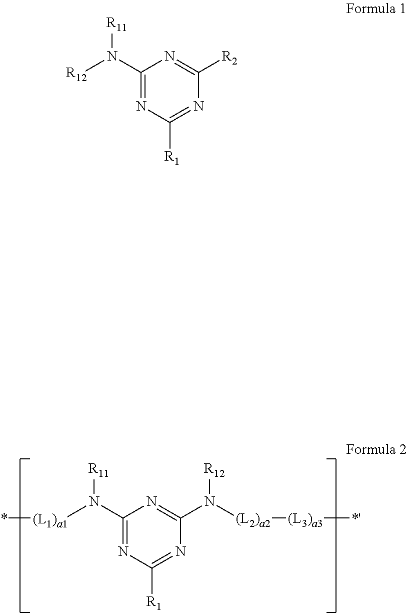

wherein, in Formulae 1 and 2,
R₁ and R₂ may each independently be:
hydrogen, a halogen atom, *—OH, *—SH, or *—C(═O)OH;
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof; or

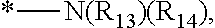

R₁₁ to R₁₄ may each independently be:
hydrogen, a halogen atom, *—OH, *—SH, or *—C(═O)OH; or
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
L₁ to L₃ may each independently be:
a single bond, O, or S; or
a C₁-C₃₀ alkylene group, a C₂-C₃₀ alkenylene group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
a1 to a3 may each independently be an integer from 1 to 30, and
* and *′ each indicate a binding site to a neighboring atom.

In an embodiment,
i) the etching controller may include a compound represented by Formula 1, or
ii) the etching controller may include a polymer including a repeating unit represented by Formula 2, or
iii) the etching controller may include a compound represented by Formula 1 and a polymer including a repeating unit represented by Formula 2.

According to an embodiment, R₁ and R₂ in Formulae 1 and 2 may each independently be

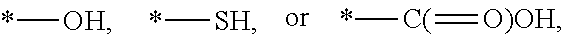

a C₁-C₁₀ alkyl group, a C₁-C₁₀ alkoxy group, or a C₁-C₁₀ alkylthio group, each unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof; or

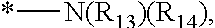

In some embodiments, R₁ and R₂ in Formulae 1 and 2 may each independently:

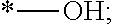 [SMILES: *O]

a C₁-C₁₀ alkyl group (e.g., a methyl group, an ethyl group, etc.) or a C₁-C₁₀ alkoxy group (e.g., a methoxy group, an ethoxy group, etc.), each unsubstituted or substituted with *—OH, a C₁-C₁₀ alkoxy group, or any combination thereof; or

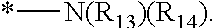

In some embodiments, R₁ in Formula 2 may be *—N(R₁₃)(R₁₄).

In some embodiments, R₁₁ to R₁₄ in Formulae 1 and 2 may each independently be:
hydrogen, *—OH, *—SH, or *—C(═O)OH; or
a C₁-C₁₀ alkyl group, a C₁-C₁₀ alkoxy group, or a C₁-C₁₀ alkylthio group, each unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof.

In some embodiments, R₁₁ to R₁₄ in Formula 1 may each independently be:
hydrogen; or
a C₁-C₁₀ alkyl group (e.g., a methyl group, an ethyl group, etc.) which is unsubstituted or substituted with *—OH, a C₁-C₁₀ alkoxy group (e.g., a methoxy group, an ethoxy group, etc.), or any combination thereof.

In some embodiments, R₁₁ to R₁₄ of Formula 2 may each independently be a C₁-C₁₀ alkyl group (e.g., a methyl group, an ethyl group, etc.) which is unsubstituted or substituted with *—OH, a C₁-C₁₀ alkoxy group (e.g., a methoxy group, an ethoxyl group, etc.), or any combination thereof.

In some embodiments, L₁ to L₃ in Formula 2 may each independently be
a single bond, O, or S; or
a C₁-C₁₀ alkylene group (e.g., a methylene group, an ethylene group, etc.) which is unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof.

In some embodiments, L₁ to L₃ in Formula 2 may each independently be:
O or S; or
a C₁-C₁₀ alkylene group (e.g., a methylene group, an ethylene group, etc.) which is unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof.

In some embodiments, a1 to a3, which are respectively the number of L₁ to the number of L₃ in Formula 2, may each independently be an integer from 1 to 5 (for example, 1 or 2). When a1 is 2 or greater, two or more of L₁ may be identical to or different from each other, when a2 is 2 or greater, two or more of L₂ may be identical to or different from each other, and when a3 is 2 or greater, two or more of L₃ may be identical to or different from each other.

In some embodiments, in Formula 2,
L₁ and L₂ may each independently be a C₁-C₁₀ alkylene group (e.g., a methylene group, an ethylene group, etc.) which is unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof,
a1 and a2 may each be 1,
L₃ may be O or S, and
a3 may be 1.

In some embodiments, the compound represented by Formula 1 may be a compound represented by Formula 1A.

In some embodiments, the repeating unit represented by Formula 2 may be a repeating unit represented by Formula 2A:

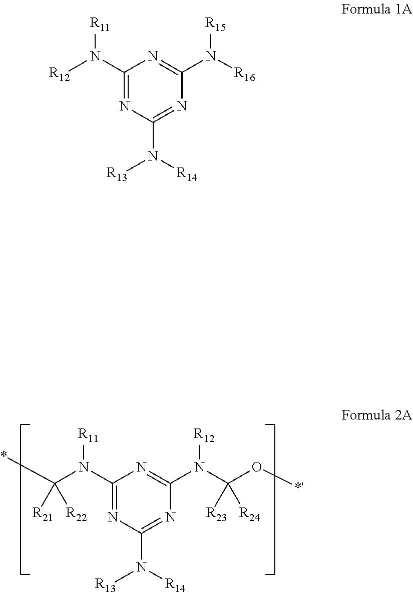

wherein, in Formulae 1A and 2A,
R₁₁ to R₁₄ are each as described herein,
R₁₅ and R₁₆ may each be as described in connection with R₁₃,
R₂₁ to R₂₄ may each independently be hydrogen, a halogen atom, *—OH, *—SH, *—C(═O)OH, a C₁-C₃₀ alkyl group, a C₂-C₃₀ alkenyl group, a C₁-C₃₀ alkoxy group, or a C₁-C₃₀ alkylthio group, and
* and *′ each indicate a binding site to a neighboring atom.

For example, R₁₁ to R₁₆ of Formula 1A may each independently be:
hydrogen; or
a C₁-C₁₀ alkyl group (e.g., a methyl group, an ethyl group, etc.) which is unsubstituted or substituted with *—OH, a C₁-C₁₀ alkoxy group (e.g., a methoxy group, an ethoxy group, etc.), or any combination thereof.

In some embodiments, R₁₁ to R₁₄ of Formula 2A may each independently be a C₁-C₁₀ alkyl group (e.g., a methyl group, an ethyl group, etc.) which is unsubstituted or substituted with *—OH, a C₁-C₁₀ alkoxy group (e.g., a methoxy group, an ethoxy group, etc.), or any combination thereof, and R₂₁ to R₂₄ may each independently be hydrogen or a methyl group.

In some embodiments, the polymer including the repeating unit represented by Formula 2 may further include any repeating unit that is different from the repeating unit represented by Formula 2. For example, a polymer including the repeating unit represented by Formula 2 may further include a repeating unit derived from a sulfur dioxide-containing compound, a repeating unit derived from an amide-containing compound, a repeating unit derived from a carboxylic acid-containing compound, or any combination thereof. For example, the amide-containing compound may include acrylamide (CH₂═CHC(O)NH₂), methacrylamide (CH₂═C(CH₃)C(O)NH₂), diacetone acrylamide, N, N-dimethylacrylamide or any combination thereof, and the carboxylic acid-containing compound may include an acrylic acid derived from an alcohol having 1 to 30 carbon atoms, a methacrylic acid derived from an alcohol having 1 to 30 carbon atoms, an unsaturated dicarboxylic acid having 1 to 30 carbon atoms (e.g., maleic acid, etc.), or any combination thereof.

In some embodiments, the weight average molecular weight of the polymer including the repeating unit represented by Formula 2 may be, for example, about 200 g/mol to about 100,000 g/mol, about 200 g/mol to about 10,000 g/mol, about 200 g/mol to about 1,000 g/mol, or about 200 g/mol to about 500 g/mol. In some embodiments, the number average molecular weight of the polymer including the repeating unit represented by Formula 2 may be, for example, about 200 to about 100,000, about 200 to about 10,000, about 200 to about 1,000, or about 200 to about 500. The weight average molecular weight and number average molecular weight may be measured, for example, using gel permeation chromatography (GPC), and may be calculated values using polystyrene.

In some embodiments, the compound represented by Formula 1 may be one of compounds 1 to 19:

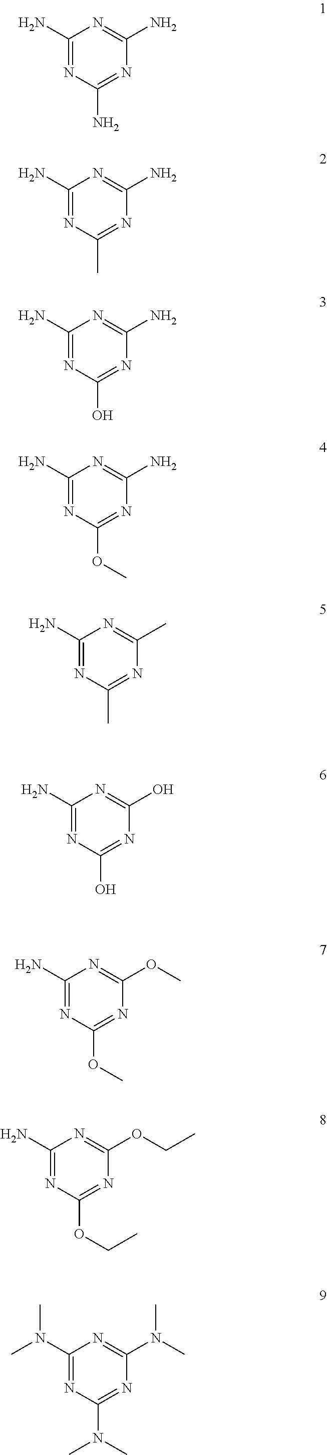

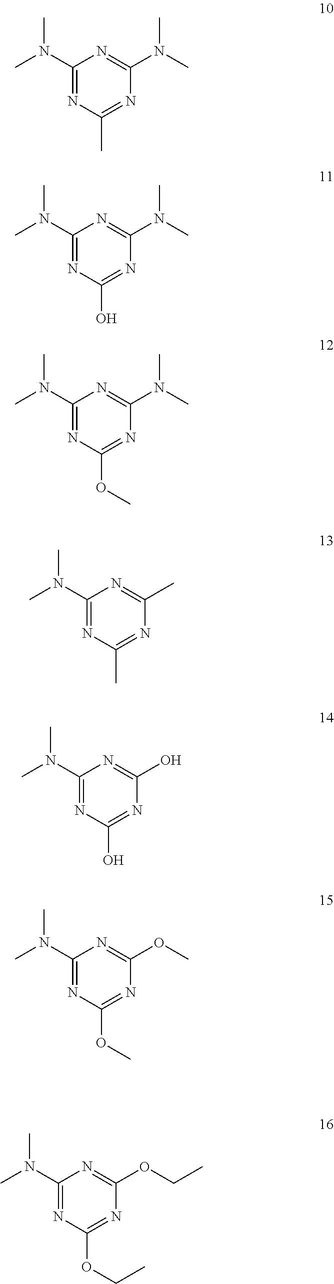

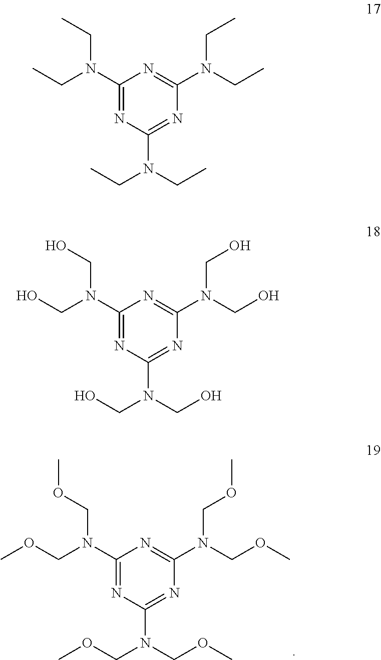

In some embodiments, the polymer including the repeating unit represented by Formula 2 may be one of polymers P1 to P4:

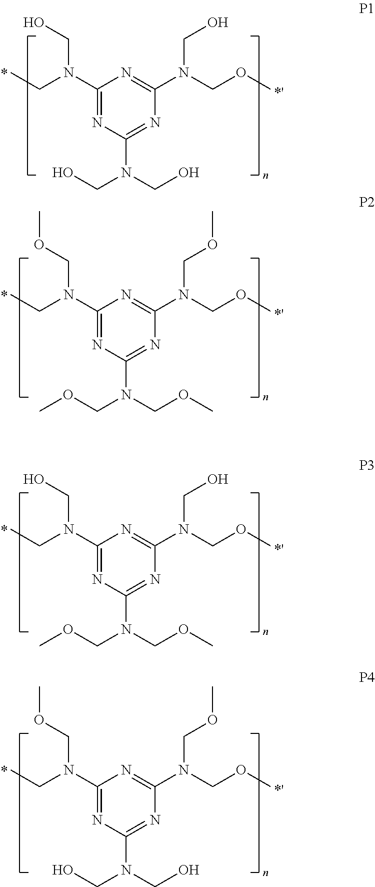

The value for n in polymer P1 to polymer P4 may be an integer greater than or equal to 2 (for example, 2 to 100,000), and each of * and *′ represents a binding site with a neighboring atom.

Each of polymer P1 to polymer P4 may have a weight average molecular weight or a number average molecular weight in such ranges as described herein.

The C₁-C₃₀ alkyl group and the C₁-C₁₀ alkyl group in the present specification may be a linear or branched alkyl group, and may be, for example, a methyl group, an ethyl group, an n-propyl group, an isopropyl group, an n-butyl group, a sec-butyl group, a tert-butyl group, etc.

The C₁-C₃₀ alkylene group and the C₁-C₁₀ alkylene group in the present specification may be a linear or branched alkylene group, and may be, for example, a methylene group, an ethylene group, etc.

Each of the C₂-C₃₀ alkenyl group, the C₂-C₁₀ alkenyl group, and the C₂-C₃₀ alkenylene group in the present specification has the same structure as the C₂-C₃₀ alkyl group, C₂-C₁₀ alkyl group and C₂-C₃₀ alkylene group described herein, and includes at least one carbon-carbon double bond in a molecule.

The C₁-C₃₀ alkoxy group and the C₁-C₁₀ alkoxy are groups represented by *—OR′ (R′ is a C₁-C₃₀ alkyl group or a C₁-C₁₀ alkyl group as described herein), and the C₁-C₃₀ alkylthio group and the C₁-C₁₀ alkylthio group are groups represented by *—SR′ (R′ is a C₁-C₃₀ alkyl group or a C₁-C₁₀ alkyl group as described herein).

The C₃-C₃₀ carbocyclic group as used herein may be, for example, a cyclopentane group, a cyclohexane group, a benzene group, a naphthalene group, etc.

The C₁-C₃₀ heterocyclic group in the present specification may be, for example, a pyridine group, a pyrimidine group, etc.

The amount (weight) of the etching controller may be, based on 100 wt % of the composition, about 0.01 wt % to about 5 wt %, about 0.01 wt % to about 4 wt %, about 0.01 wt % to about 3 wt %, about 0.01 wt % to about 2 wt %, about 0.01 wt % to about 1.5 wt %, about 0.01 wt % to about 1 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1.5 wt %, about 0.05 wt % to about 1 wt %, about 0.1 wt % to about 5 wt %, about 0.1 wt % to about 4 wt %, about 0.1 wt % to about 3 wt %, about 0.1 wt % to about 2 wt %, about 0.1 wt % to about 1.5 wt %, about 0.1 wt % to about 1 wt %, about 0.5 wt % to about 5 wt %, about 0.5 wt % to about 4 wt %, about 0.5 wt % to about 3 wt %, about 0.5 wt % to about 2 wt %, or about 0.5 wt % to about 1.5 wt %. When the etching controller includes a polymer including the repeating unit represented by Formula 2, the amount of the polymer refers to the amount of the solid content of the polymer.

According to an embodiment, the etching controller may include the compound represented by Formula 1 and the polymer including the repeating unit represented by Formula 2, and a weight ratio of the compound represented by Formula 1 and the polymer including the repeating unit represented by Formula 2 (based on polymer solid content) may be in the range of 1:1 to 1:100, the range of 1:3 to 1:50, or the range of 1:3 to 1:10. For example, the etching controller may include the compound represented by Formula 1 and the polymer including the repeating unit represented by Formula 2, and a weight ratio of the compound represented by Formula 1 to the polymer including the repeating unit represented by Formula 2 (based on polymer solid content) may be 1:5.

pH

The composition as described above may have a pH of 5.0 or less, 4.0 or less, 3.0 or less, 2.2 or less, 2.0 or less, 1.0 or less, 0.5 or less, 0 or less, about −3.0 to about 5.0, about −3.0 to about 4.0, about −3.0 to about 3.0, about −3.0 to about 2.2, about −3.0 to about 2.0, about −3.0 to about 1.0, about −3.0 to about 0.5, about −3.0 to about 0, about −2.5 to about 5.0, about −2.5 to about 4.0, about −2.5 to about 3.0, about −2.5 to about 2.2, about −2.5 to about 2.0, about −2.5 to about 1.0, about −2.5 to about 0.5, about −2.5 to about 0, about −2.0 to about 5.0, about −2.0 to about 4.0, about −2.0 to about 3.0, about −2.0 to about 2.2, about −2.0 to about 2.0, about −2.0 to about 1.0, about −2.0 to about 0.5, about −2.0 to about 0, about −1.5 to about 5.0, about −1.5 to about 4.0, about −1.5 to about 3.0, about −1.5 to about 2.2, about −1.5 to about 2.0, about −1.5 to about 1.0, about −1.5 to about 0.5, about −1.5 to about 0, about −1.0 to about 5.0, about −1.0 to about 4.0, about −1.0 to about 3.0, about −1.0 to about 2.2, about −1.0 to about 2.0, about −1.0 to about 1.0, about −1.0 to about 0.5, about −1.0 to about 0, about −0.6 to about 5.0, about −0.6 to about 4.0, about −0.6 to about 3.0, about −0.6 to about 2.2, about −0.6 to about 2.0, about −0.6 to about 1.0, about −0.6 to about 0.5, or about −0.6 to about 0. In case that the composition has such pH ranges as described above, the interaction between the etching controller and metal atoms in the metal-containing film may occur more smoothly.

According to an embodiment, the composition may include about 0.001 wt % to about 10 wt % of the oxidizing agent, about 10 wt % to about 85 wt % of the acid, and about 0.01 wt % to about 3 wt % of the etching controller.

According to an embodiment, the composition may include about 0.001 wt % to about 5 wt % of the oxidizing agent, about 10 wt % to about 88 wt % of the acid, and about 0.01 wt % to about 5 wt % of the etching controller.

According to an embodiment, the composition may include about 0.001 wt % to about 5 wt % of the oxidizing agent, about 10 wt % to about 85 wt % of the acid, and about 0.01 wt % to about 5 wt % of the etching controller.

According to an embodiment, the composition may be used in a metal-containing film treatment process, for example, an etching process, a cleaning process, or the like, for a metal-containing film. The metal-containing film is as described herein.

Alternatively, the composition may also be used as an etching by-product remover, a post-etch process by-product remover, an ashing process by-product remover, a cleaning composition, a photoresist (PR) remover, an etching composition for packaging process, a cleaner for packaging process, a wafer adhesive material remover, an etchant, a post-etch residue stripper, an ash residue cleaner, a photoresist residue stripper, a chemical mechanical polishing (CMP) cleaner, or a post-CMP cleaner.

### Method of Treating a Metal-Containing Film

Using the composition as described above, a metal-containing film including a first region and a second region, wherein the material included in the first region is different from the material included in the second region, may be more effectively treated. For a description of each of the metal-containing film, the first region and the second region, reference is made to the description herein.

According to an embodiment, the first region and the second region may independently include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof.

According to another embodiment, the first region may include titanium (Ti), indium (In), aluminum (Al), lanthanum (La), scandium (Sc), gallium (Ga), or any combination thereof, and the second region may include tungsten (W), molybdenum (Mo), ruthenium (Ru), or any combination thereof.

According to another embodiment, the first region may include a metal nitride, a metal oxynitride, or any combination thereof, and the second region may include a conductive metal.

According to another embodiment, the first region may include a titanium nitride, a titanium oxynitride, or any combination thereof, and each of the titanium nitride and the titanium oxynitride may optionally further include indium (In), aluminum (Al), lanthanum (La), scandium (Sc), gallium (Ga), silicon (Si), or any combination thereof.

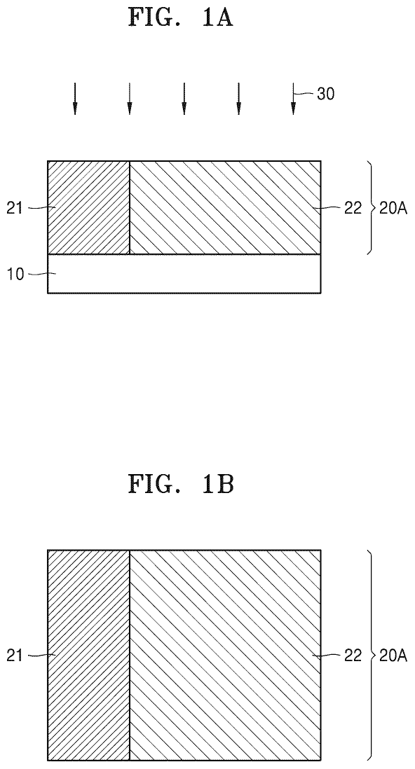

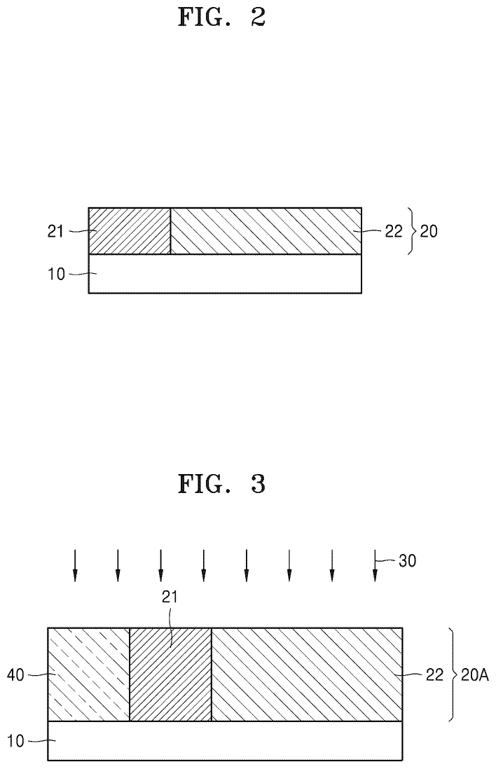

FIGS. 1A and 2 are views schematically illustrating an embodiment of a metal-containing film treatment method.

Referring to FIG. 1A, a substrate 10 having a metal-containing film 20A is provided. Although not shown in FIG. 1A, various circuit elements or the like may optionally be additionally disposed between the substrate 10 and the metal-containing film 20A.

The metal-containing film 20A may include a first region 21 and a second region 22. The first region 21 and the second region 22 may be disposed apart from each other, or may be disposed at least partially in contact with each other, and the metal-containing film 20A may have various patterns. The metal-containing film 20A, including the first region 21 and the second region 22, may come into contact with composition 30, whereby a portion of the metal-containing film 20A may be removed. For example, during an etching, cleaning and/or polishing process of the metal-containing film 20A, the metal-containing film 20A may come into contact with the composition 30. The composition 30 may include the oxidizing agent, the acid and the etching controller as described in the specification, and for a detailed description thereof, reference is made to the description herein.

An etching rate ratio, which is obtained by dividing a first etching rate at which the composition 30 etches the first region 21 by a second etching rate at which the composition 30 etches the second region 22, may be 0.04 or more. For example, the etching rate ratio, which is obtained by dividing the first etching rate at which the composition 30 etches the first region 21 by the second etching rate at which the composition 30 etches the second region 22, may be about 0.05 or more, about 0.06 or more, about 0.04 to about 1.0, about 0.05 to about 1.0, about 0.06 to about 1.0, about 0.04 to about 0.5, about 0.05 to about 0.5, about 0.06 to about 0.5, about 0.04 to about 0.3, about 0.05 to about 0.3, about 0.06 to about 0.3, about 0.04 to about 0.2, about 0.05 to about 0.2, about 0.06 to about 0.2, about 0.04 to about 0.15, about 0.05 to about 0.15, about 0.06 to about 0.15, or about 0.06 to about 0.13.

FIG. 1B is a view schematically illustrating a surface of a metal-containing film 20A that may be in contact with a composition 30. An etching area ratio, which is obtained by dividing a first area of a first region 21 exposed for contact with the composition 30 by a second area of a second region 22 exposed for contact with the composition 30, may be about 0.05 to about 1.0, about 0.05 to about 0.9, about 0.05 to about 0.7, about 0.05 to about 0.5, about 0.05 to about 0.4, about 0.05 to about 0.3, or about 0.05 to about 0.2.

When the metal-containing film 20A comes into contact with the composition 30, the high reactivity of metals included in the metal-containing film 20A (for example, a metal such as molybdenum contained in the second region 22) may be controlled through the interaction of the oxidizing agent, the acid and the etching controller included in composition 30. As a result, the etch rate of the region containing a relatively highly reactive metal (for example, the etch rate of second region 22) among the first region 21 and the second region 22 may be properly controlled. Accordingly, portions of both the first region 21 and the second region 22 may be etched such that a metal-containing film pattern 20 having a substantially planar surface (for example, having little or no step height difference between the first region 21 and the second region 22), as illustrated in FIG. 2, may be formed.

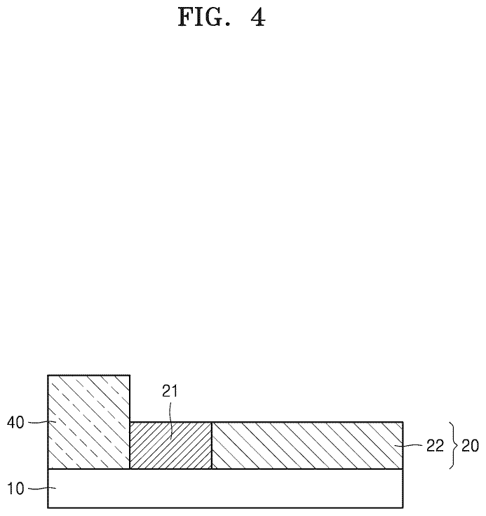

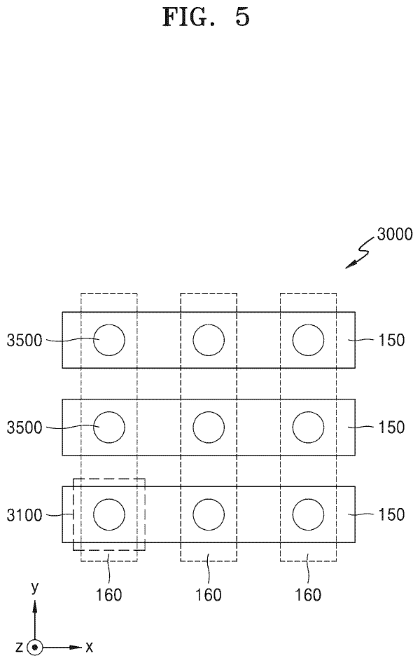

FIGS. 3 and 4 are views schematically illustrating other embodiments of the metal-containing film treatment method.

Referring to FIG. 3, a substrate 10 is provided in which, in addition to the metal-containing film 20A, an additional material 40 is provided adjacent to the metal-containing film 20A. For a description of each of the metal-containing film 20A and the substrate 10 of FIG. 3, reference is made to FIG. 1A.

The additional material 40 in FIG. 3 may be disposed spaced apart from the metal-containing film 20A or may be at least partially in contact with it. As used herein, the term “the additional material 40” refers to a material other than the metal-containing film 20A, which is disposed adjacent to metal-containing film 20A and is located in a region that may be affected by the composition 30 during the treatment of metal-containing film 20A using the composition 30.

The additional material 40 may include at least one of an insulating material and a semiconductor material. The insulating material and semiconductor material may include various known materials.

The insulating material may include various oxides, nitrides, oxynitrides, high-dielectric materials, or combinations thereof. For example, the insulating material may include silicon oxide, silicon nitride, silicon oxynitride, aluminum oxide, hafnium oxide, hafnium oxynitride, zirconium oxide, or a combination thereof. The hafnium oxide and hafnium oxynitride may optionally further include Si, Ta, Ti, Zr or any combination thereof. As another example, the insulating material may include tetraethyl orthosilicate (TEOS), hydrogen silsesquioxane (HSQ), methyl silsesquioxane (MSQ), or the like.

The semiconductor material may be, for example, a material included in a channel or the like, and may include: a Group IV semiconductor material such as silicon, germanium (Ge), silicon-germanium (SiGe), and silicon carbide (SiC); a Group III-V semiconductor material such as gallium arsenide (GaAs), indium arsenide (InAs), and indium phosphide (InP); as well as an oxide semiconductor, a nitride semiconductor, and an oxynitride semiconductors. The oxide semiconductor may include, for example, Indium Gallium Zinc Oxide (IGZO), Indium Tin Zinc Oxide (ITZO), Indium Tin Gallium Oxide (ITGO), Indium Tungsten Oxide (IWO), Indium Tin Oxide (ITO), ZnO, Cu₂O, or any combination thereof.

As shown in FIG. 3, the metal-containing film 20A including the first region 21 and the second region 22, and the additional material 40, may be brought into contact with the composition 30, and a portion of the metal-containing film 20A may be removed. For example, during an etching, cleaning, and/or polishing process of the metal-containing film 20A including the first region 21 and the second region 22, the metal-containing film 20A may be brought into contact with the composition 30. The composition 30 includes the oxidizing agent, the acid and the etching controller as described in this specification, and for a detailed description thereof, reference is made to the description herein.

When the metal-containing film 20A comes into contact with the composition 30, a portion of the metal-containing film 20A may be removed. Specifically, upon contact between the metal-containing film 20A and the composition 30, due to the interaction among the oxidizing agent, the acid and the etching controller included in composition 30, the high reactivity of the metal included in the metal-containing film 20A (for example, a metal such as molybdenum included in second region 22) may be controlled. As a result, the etch rate of the region including a relatively highly reactive metal among the first region 21 and the second region 22 (for example, the etch rate of the second region 22) may be appropriately controlled, such that portions of both the first region 21 and the second region 22 are etched. Accordingly, as illustrated in FIG. 4, a metal-containing film pattern 20 having a substantially planar surface (for example, with little or no step height difference between the first region 21 and the second region 22) may be formed. In addition, for example, the additional material 40, which includes at least one of an insulating material and a semiconductor material, may remain substantially undamaged by the composition 30.

### Method of Manufacturing an Electronic Device

Using the composition described above, a high-quality electronic device may be manufactured. Accordingly, a method of manufacturing an electronic device using the composition may be provided.

According to an aspect of the disclosure,
a method of manufacturing an electronic device including a transistor is provided,
wherein the transistor includes,
a channel;
a source and a drain spaced apart from each other and electrically connected to the channel;
a gate electrode; and
a gate insulating film disposed between the gate electrode and the channel,
wherein the method includes:
providing a barrier layer including a metal nitride, a metal oxynitride, or a combination thereof;
providing a conductive layer including a conductive metal; and
forming the gate electrode by bringing the barrier layer and the conductive layer into contact with the composition to etch a portion of the barrier layer and a portion of the conductive layer.

According to an aspect of the disclosure, a method of manufacturing an electronic device may include: forming a structure including a source and a drain spaced apart from each other and electrically connected to a channel; and providing a gate electrode and a gate insulating film on the structure, wherein the gate insulating film is between the gate electrode and the channel. The gate electrode may be provided by: providing a barrier layer comprising a metal nitride, a metal oxynitride, or any combination thereof; providing a conductive layer including a conductive metal; and forming the gate electrode by bringing the barrier layer and the conductive layer into contact with the composition to etch a portion of the barrier layer and a portion of the conductive layer.

The channel may include, for example, a semiconductor material as described herein. For example, the channel may include: a Group IV semiconductor material such as silicon, germanium (Ge), silicon-germanium (SiGe), and silicon carbide (SiC); a Group Ill-V semiconductor material such as gallium arsenide (GaAs), indium arsenide (InAs), and indium phosphide (InP); an oxide semiconductor, a nitride semiconductor, and an oxynitride semiconductors. The oxide semiconductor may include, for example, Indium Gallium Zinc Oxide (IGZO), Indium Tin Zinc Oxide (ITZO), Indium Tin Gallium Oxide (ITGO), Indium Tungsten Oxide (IWO), Indium Tin Oxide (ITO), ZnO, Cu₂O, or any combination thereof.

The gate insulating film may include an insulating material capable of electrically insulating the gate electrode and the channel. For example, the gate insulating film may include various oxides, nitrides, oxynitrides, high-k materials, or a combination thereof. For example, the gate insulating film may include silicon oxide, silicon nitride, silicon oxynitride, aluminum oxide, hafnium oxide, hafnium oxynitride, zirconium oxide, or a combination thereof. The hafnium oxide and hafnium oxynitride may optionally further include Si, Ta, Ti, Zr or any combination thereof.

The gate electrode may include a barrier layer and a conductive layer. The barrier layer may be disposed, for example, between the gate insulating film and the conductive layer.

In order to provide the gate electrode, a barrier layer and a conductive layer may be provided. For example, after forming the barrier layer, the conductive layer may be formed on the surface of the barrier layer. However, depending on the structure of the channel and/or gate electrode, various modifications are possible, such as forming the barrier layer on the surface of the conductive layer after the conductive layer is formed.

The barrier layer may be provided to limit and/or prevent peripheral diffusion of a conductive metal (for example, metal ion) included in the conductive layer and/or to facilitate smooth deposition of the conductive layer.

For a detailed description of each of the metal nitride and/or metal oxynitride that may be included in the barrier layer, reference may be made to the description of each of the metal nitride and/or metal oxynitride that may be included in the first region of the metal-containing film in this specification herein.

According to an embodiment, the barrier layer may include a titanium nitride, a titanium oxynitride, or a combination thereof, and each of the titanium nitride and the titanium oxynitride may optionally further comprise indium (In), aluminum (Al), lanthanum (La), scandium (Sc), gallium (Ga), silicon (Si), or any combination thereof.

For a detailed description of the conductive metal that may be included in the conductive layer, reference may be made to the description of the conductive metal that may be included in the second region of the metal-containing film herein.

According to an embodiment, the conductive layer may include tungsten (W), molybdenum (Mo), ruthenium (Ru), or any combination thereof.

Subsequently, the barrier layer and the conductive layer may be brought into contact with the composition described herein to etch a portion of the barrier layer and a portion of the conductive layer, thereby forming the gate electrode.

When the barrier layer and the conductive layer are brought into contact with the composition as described herein, the high reactivity of the conductive metal included in the conductive layer may be controlled through the interaction among the oxidizing agent, the acid and the etching controller in the composition. As a result, the etch rate of the conductive layer may be properly controlled, allowing for etching of portions of both the barrier layer and the conductive layer. Accordingly, a gate electrode having a substantially planar surface (for example, with little or no step height difference between the barrier layer and the conductive layer) may be formed. In addition, since at least one of the channel and gate insulating films disposed adjacent to the gate electrode may be substantially undamaged by the composition, a high-quality electronic device including a gate electrode having a precise pattern may be manufactured without damage to an area adjacent to the gate electrode.

The electronic device may be a semiconductor memory device.

For example, the electronic device may include a volatile memory device, such as a dynamic random access memory (“DRAM”) device or a static random access memory (“SRAM”) device, a resistive random access memory (“ReRAM”) device, an electrically erasable programmable read-only memory (“EEPROM”) device, a flash memory (which may also be considered a subset of EEPROM) device, a ferroelectric random access memory (“FRAM”) device, a magnetoresistive random access memory (“MRAM”) device, and a nonvolatile memory device such as other semiconductor devices capable of storing information.

According to an embodiment, the electronic device may be a DRAM device.

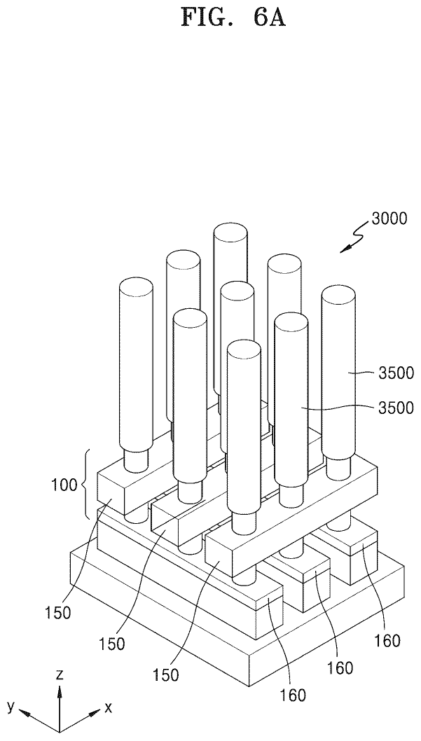

Hereinafter, the manufacturing method of the electronic device will be described in more detail with reference to FIGS. 5, 6A, 6B, 7, 8 and 9.

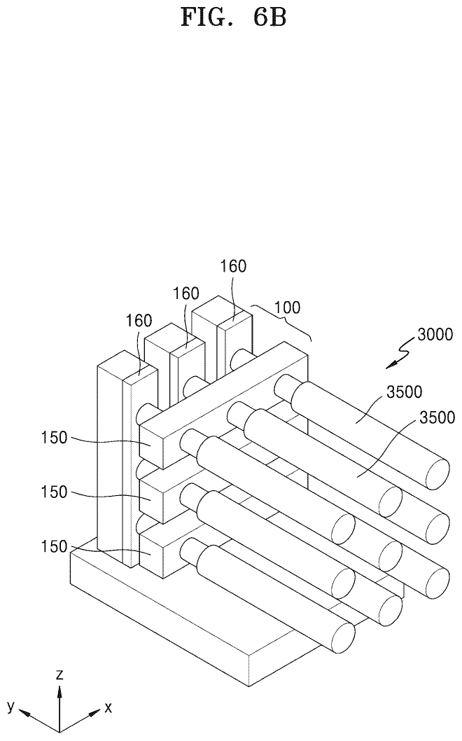

FIG. 5 is a schematic plan view of an electronic device 3000 according to an embodiment, and FIGS. 6A and 6B are each a perspective view of the electronic device 3000 shown in FIG. 5. The electronic device 3000 of FIG. 5 may be a DRAM device.

Referring to FIGS. 5, 6A and 6B, the electronic device 3000 includes a plurality of unit elements 3100 arranged in an array form. Each unit element 3100 has a 1T1C structure including (or consisting of) one transistor and one capacitor.

The electronic device 3000 includes a transistor structure 100 and a plurality of capacitors 3500 provided to the transistor structure 100. The transistor structure 100 may be, for example, a vertical channel array transistor structure including channels arranged vertically with respect to the substrate (see FIG. 6A), or a channel array transistor structure including channels arranged and stacked horizontally with respect to the substrate (see FIG. 6B).

In the transistor structure 100, a plurality of gate electrodes (or word lines) 150 and a plurality of bit lines 160 are provided to intersect each other. Each gate electrode 150 may be provided to extend in a first direction (for example, the x-axis direction), and each bit line 160 may be provided to extend in a second direction (for example, the y-axis direction) intersecting the first direction. Transistors are arranged at points where the plurality of gate electrodes 150 and the plurality of bit lines 160 intersect.

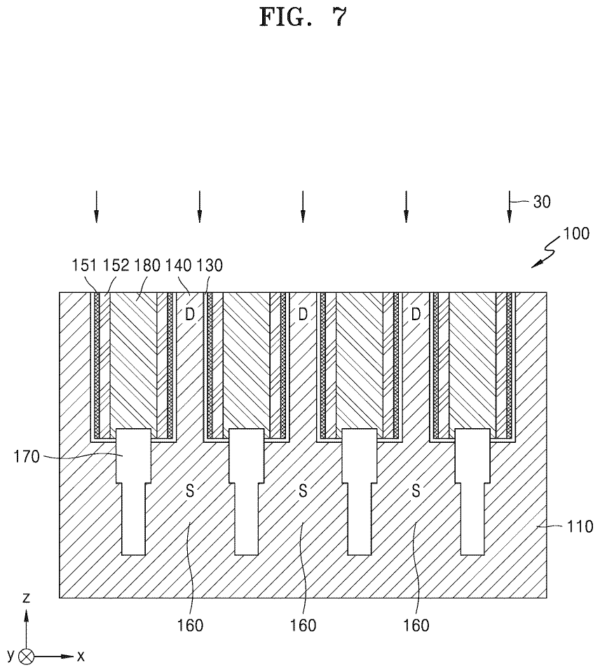

FIGS. 7 to 9 are views schematically illustrating part of the manufacturing process of the transistor structure 100 illustrated in FIG. 6A.

In FIG. 7, the transistor structure 100 includes a substrate 110 and a plurality of channels 140 arranged in an array form on the substrate 110. The plurality of channels 140 may be arranged in a two-dimensional array form on a plane (for example, xy-plane) of the substrate 110.

The substrate 110 may include a semiconductor, for example, silicon (Si). As a specific example, the substrate 110 may be a silicon substrate doped with an n-type impurity. However, this is merely illustrative. Alternatively, the substrate 110 may include, for example, a Group IV semiconductor material such as germanium (Ge), silicon-germanium (SiGe), or silicon carbide (SiC); a Group III-V semiconductor material such as gallium arsenide (GaAs), indium arsenide (InAs), or indium phosphide (InP); or an oxide semiconductor, nitride semiconductor, oxynitride semiconductor or the like.

Each of the plurality of channels 140 may be provided to extend vertically from the substrate 110. Each channel 140 may be provided to protrude vertically from the upper surface of the substrate 110. Each channel 140 may be formed integrally with the substrate 110 and thus may include the same semiconductor material as the semiconductor substrate 110. In FIG. 7, the channels 140 are shown formed integrally with the substrate 110, but various modifications are possible, such as the channel 140 being formed separately from the substrate 110.

A source (S) and a drain (D) are provided at the bottom and top of each channel 140, respectively. The source (S) is provided to be electrically connected to the bottom of the channel 140, and the drain (D) is provided to be connected to the top of the channel 140. For example, the source (S) and drain (D) may be formed through the formation of a doped region. The capacitor 3500 illustrated in FIG. 5 may be connected to a drain (D) provided at the upper portion of the channel 140.

On the top surface of the substrate 110, sources (S) are provided in an array form corresponding to channels 140. Beneath the sources (S), a plurality of bit lines 160 are provided to extend along a second direction (for example, the y-axis direction). Each bit line 160 may electrically connect the sources (S) arranged along the second direction. The plurality of bit lines 160 may be formed within the substrate 110 and thus may include the same semiconductor material as the substrate 110. In FIG. 7, the bit lines 160 are formed using a material separate from the substrate 110; however, various modifications are possible.

A plurality of insulating materials 170 may be provided in the substrate 110 between the bit lines 160. The plurality of insulating materials 170 may be provided to extend along the second direction, in parallel with the plurality of bit lines 160, thereby separating the plurality of bit lines 160 within the substrate 110. The insulating material 170 may include, for example, silicon oxide, silicon nitride, silicon oxynitride, aluminum oxide, hafnium oxide, hafnium oxynitride, zirconium oxide, or a combination thereof.

A gate insulating film 130 is provided on the surface of the channels 140. The gate insulating film 130 may include an insulating material as described herein, for example, silicon oxide, silicon nitride, silicon oxynitride, aluminum oxide, hafnium oxide, hafnium oxynitride, zirconium oxide, or a combination thereof.

In the substrate 110 provided with the channels 140 and the gate insulating film 130 as described above, a barrier layer 151 including a metal nitride, a metal oxynitride, or a combination thereof, and a conductive layer 152 including a conductive metal, are provided in a trench defined at least in part by the gate insulating film 130, as illustrated in FIG. 7. For example, after forming the barrier layer 151, the conductive layer 152 may be formed on the surface of the barrier layer 151. However, depending on the structure of the channels 140 and/or gate electrode 150, various modifications are possible, such as forming the barrier layer 151 on the surface of the conductive layer 152 after the conductive layer 152 is formed. For a description of the metal nitride and/or metal oxynitride included in the barrier layer 151, and of the conductive metal included in the conductive layer 152, reference is made to the descriptions herein.

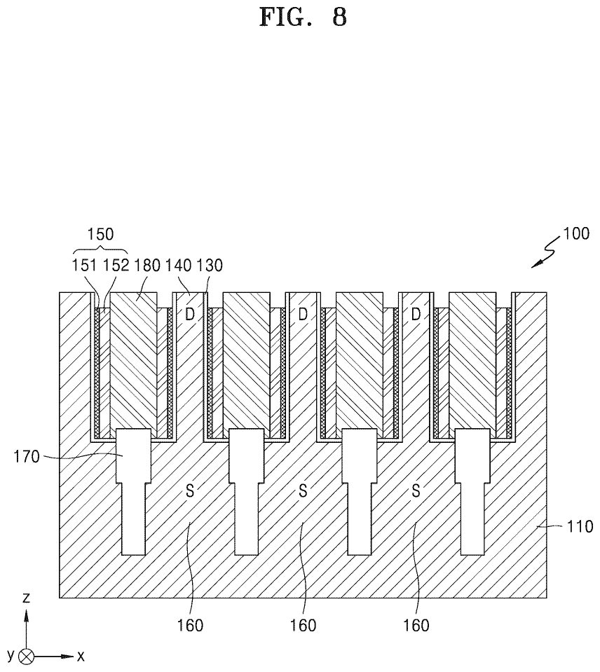

Subsequently, as illustrated in FIG. 7, an embedded insulating layer 180 is provided within a trench at least partially defined by the conductive layer 152. The embedded insulating layer 180 may serve to protect the gate electrode 150 of FIG. 8 from the penetration of oxygen and the like. After forming the embedded insulating layer 180, a planarization process may additionally be performed so that the top surfaces of the barrier layer 151 and the conductive layer 152 are exposed.

Then, the exposed top surfaces of the barrier layer 151 and the conductive layer 152 are brought into contact with the composition 30 to etch a portion of the barrier layer 151 and a portion of the conductive layer 152, thereby forming the gate electrode 150 having the pattern shown in FIG. 8. The composition 30 in FIG. 7 includes the oxidizing agent, the acid and the etching controller as described in this specification, and for a detailed description thereof, reference is made to the descriptions herein.

An etching rate ratio, which is obtained by dividing a first etching rate at which the composition 30 etches the barrier layer 151 by a second etching rate at which the composition 30 etches the conductive layer 152, may be 0.04 or more. For example, the etching rate ratio, which is obtained by dividing the first etching rate at which the composition 30 etches the barrier layer 151 by the second etching rate at which the composition 30 etches the conductive layer 152, may be 0.05 or more, about 0.06 or more, about 0.04 to about 1.0, about 0.05 to about 1.0, about 0.06 to about 1.0, about 0.04 to about 0.5, about 0.05 to about 0.5, about 0.06 to about 0.5, about 0.04 to about 0.3, about 0.05 to about 0.3, about 0.06 to about 0.3, about 0.04 to about 0.2, about 0.05 to about 0.2, about 0.06 to about 0.2, about 0.04 to about 0.15, about 0.05 to about 0.15, about 0.06 to about 0.15, or about 0.06 to about 0.13.

Meanwhile, an etching area ratio, which is obtained by dividing a first area of the barrier layer 151 exposed for contact with the composition 30 by a second area of the conductive layer 152 exposed for contact with the composition 30, may be about 0.05 to about 1.0, about 0.05 to about 0.9, about 0.05 to about 0.7, about 0.05 to about 0.5, about 0.05 to about 0.4, about 0.05 to about 0.3, or about 0.05 to about 0.2.

When the barrier layer 151 and the conductive layer 152 come into contact with the composition 30, the higher reactivity of the conductive metal included in the conductive layer 152 may be controlled through the interaction among the oxidizing agent, the acid and the etching controller included in the composition 30. As a result, the etch rate of the conductive layer 152 may be appropriately controlled, and portions of both the barrier layer 151 and the conductive layer 152 may be etched. Accordingly, as illustrated in FIG. 8, a gate electrode 150 having a substantially planar top surface (for example, with little or no step height difference between the barrier layer 151 and the conductive layer 152) may be formed. In addition, the channel 140, the gate insulating film 130, and the embedded insulating layer 180 arranged adjacent to the gate electrode 150 may be substantially undamaged by the composition 30, so that a high-quality electronic device 3000 including a gate electrode 150 having a precise pattern may be manufactured without damage to an area adjacent to the gate electrode 150, for example, the channel 140, the gate insulating film 130, and the embedded insulating layer 180.

In FIG. 8, the plurality of gate electrodes 150 on the substrate 110 may be arranged to extend along a first direction (for example, the x-axis direction). The first direction may be a direction intersecting with the second direction described above. For example, the first direction may be a direction perpendicular to the second direction. However, it is not necessarily limited thereto.

Each gate electrode 150 is provided to correspond to the channels 140 arranged along the first direction. Specifically, each gate electrode 150 may be provided to surround the channels 140 arranged along the first direction. These gate electrodes 150 may function as word lines.

The plurality of gate electrodes 150 may be provided to intersect with a plurality of insulating materials 170 provided thereunder. The top surface of the insulating materials 170 may be provided so as to be adjacent to the bottom surface of the gate electrodes 150. The top of the insulating materials 170 may be provided to protrude from the bottom of the gate electrodes 150, but is not limited thereto.

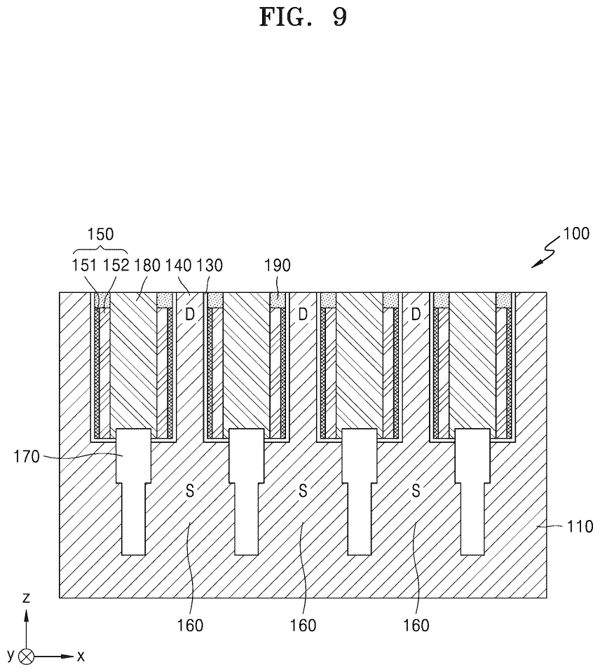

Subsequently, as shown in FIG. 9, an insulating layer 190 may be additionally provided on the surface of the etched barrier layer 151 and the surface of the etched conductive layer 152. The insulating layer 190 may serve to further insulate the gate electrode 150 from the channel 140, and may include, for example, an insulating material as described herein.

### Method of Manufacturing an Electronic Apparatus

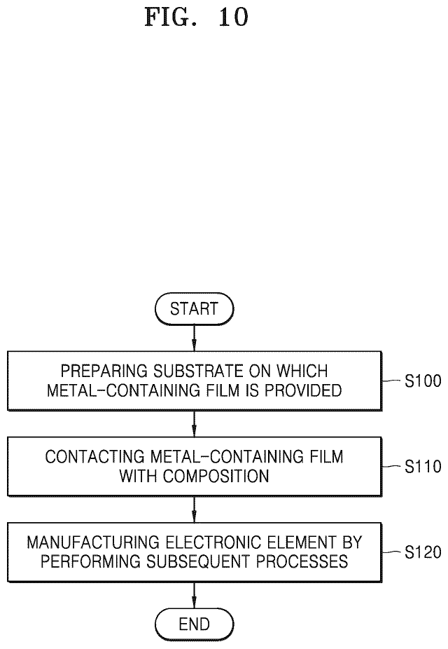

Referring to FIG. 10, an embodiment of a method of manufacturing an electronic apparatus may include: preparing a substrate on which is provided a metal-containing film (S100); bringing the metal-containing film into contact with a composition as described herein (S110); and manufacturing the electronic element using one or more subsequent processes (S120). The subsequent processes may include various known processes for manufacturing electronic elements, such as a capacitor formation process.

### Examples 1 to 4, Comparative Examples C1 and C2

The compositions of Examples 1 to 4, Comparative Example C1 and Comparative Example C2 were prepared by mixing an oxidizing agent, an acid, and an etching controller, materials of which were weighed according to the amounts described in Table 1. The remainder of each composition corresponds to water (deionized water). The number average molecular weight (Mₙ) of polymer P1 is 432, and the amount of polymer P1 described in Table 1 refers to the amount of solid content of polymer P1. The compositions of Examples 1 to 3 and Comparative Example C2 include one compound as an etching controller, the composition of Example 4 includes two compounds as an etching controller, the composition of Comparative Example C1 does not include an etching controller, and the composition of Comparative Example C2 does not include an oxidizing agent.

### Evaluation Example 1

The composition of Example 1 was placed in each of three beakers and heated to 60° C., and then a titanium nitride-containing film specimen, a molybdenum film specimen, and a silicon oxide film specimen, each having the size of 1 cm×1 cm, were respectively immersed in the beakers for 1 minute, and then the thickness of each of the titanium nitride-containing film, the molybdenum film, and the silicon oxide film was measured by using an ellipsometer (M-2000, J.A. Woolam), a four-point resistance meter, and X-ray fluorescence spectroscopy (XRF) to obtain the rate at which the composition of Example 1 etches the titanium nitride-containing film (also referred to as the “titanium nitride-containing film etching rate”), the rate at which the composition of Example 1 etches the molybdenum film (also referred to as the “molybdenum film etching rate”), and the rate at which the composition of Example 1 etches the silicon oxide film (also referred to as the “silicon oxide film etching rate”). The unit of the etching rate of each film is “A/min”. Thereafter, the molybdenum film etching rate “A” was divided by the titanium nitride-containing film etching rate “B” to evaluate the ratio of the molybdenum film etching rate to the titanium nitride-containing film etching rate, “A/B”.

The test was repeatedly performed by using each of the compositions of Examples 2 to 4 and Comparative Example C1 and Comparative Example C2, and the molybdenum film etching rate of each of the compositions of Examples 1 to 4 and Comparative Example C2 was summarized in Table 1 as a relative value (%) to the molybdenum film etching rate of the composition of Comparative Example C1, and A/B of each of the compositions of Examples 1 to 4 and Comparative Example C2 was summarized in Table 1 as a relative value (%) to A/B of the composition of Comparative Example C1. The pH values of the compositions of Examples 1 to 4, Comparative Examples C1 and C2, as evaluated by a pH meter, are also summarized in Table 1.

TABLE 1

| | | | | | | Molybdenum | | Silicon |
|---|---|---|---|---|---|---|---|---|
| | | | | | | film | | oxide |
| | | | | | | etching | | film |
| | | | | | | rate | A/B | etching |
| | Oxidizing | | Etching | | | (relative | (relative | rate |
| | agent | Acid | controller | | pH | value, %) | value, %) | (Å/min) |
| Example 1 | Hydrogen | Phosphoric | 1 | | −0.522 | 42 | 25 | <1 |
| | peroxide | acid | (0.5 wt %) | | | | | |
| | (0.5 wt %) | (60 wt %) | | | | | | |
| Example 2 | Hydrogen | Phosphoric | P1 | | −0.429 | 28 | 20 | <1 |
| | peroxide | acid | (0.5 wt %) | | | | | |
| | (0.5 wt %) | (60 wt %) | | | | | | |
| Example 3 | Hydrogen | Phosphoric | P1 | | −0.335 | 21 | 37 | <1 |
| | peroxide | acid | (1.0 wt %) | | | | | |
| | (0.5 wt %) | (60 wt %) | | | | | | |
| Example 4 | Hydrogen | Phosphoric | 1 | P1 | −0.489 | 18 | 14 | <1 |
| | peroxide | acid | (0.1 wt %) | (0.5 wt %) | | | | |
| | (0.5 wt %) | (60 wt %) | | | | | | |
| Comparative | Hydrogen | Phosphoric | — | | −0.595 | 100 | 100 | <1 |
| Example | peroxide | acid | | | | | | |
| C1 | (0.5 wt %) | (60 wt %) | | | | | | |
| Comparative | — | Phosphoric | 1 | | −0.565 | 0 | 0 | <1 |
| Example | | acid | (0.5 wt %) | | | | | |
| C2 | | (60 wt %) | | | | | | |

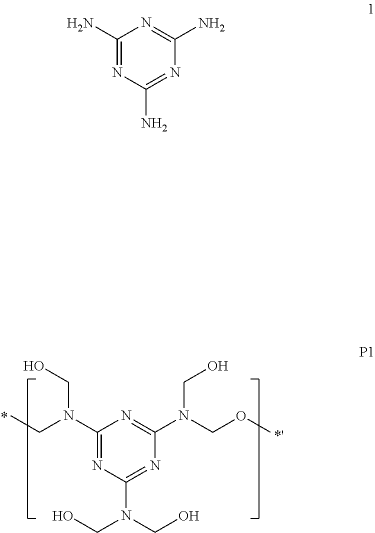

From Table 1, if the molybdenum film and the titanium nitride-containing film are etched simultaneously, it can be confirmed that i) the composition of Comparative Example C1 that does not include an etching controller excessively etches the molybdenum film compared to the compositions of Examples 1 to 4, and ii) the composition of Comparative Example C2 that does not include an oxidizing agent does not etch the molybdenum film. On the other hand, it can be confirmed that the compositions of Examples 1 to 4 can simultaneously etch both the titanium nitride-containing film and the molybdenum film at a more appropriate etching ratio without substantially damaging the silicon oxide film and without excessively etching the molybdenum film, and thus can be usefully used for more uniform etching of metal-containing films having various compositions.

### Example 5 and Comparative Example C3

The compositions of Example 5 and Comparative Example C3 were prepared by mixing an oxidizing agent, an acid, and an etching controller, materials of which were weighed according to the amounts described in Table 2. The compositions of Example 5 and Comparative Example C3 include two compounds as acids.

### Evaluation Example 2

For the composition of Example 5 and Comparative Example C3, a pH and a molybdenum film etching rate were evaluated according to the method described in Evaluation Example 1. Results thereof are summarized in Table 2. In Table 2, the molybdenum film etching rate of the composition of Example 5 was expressed as a relative value (%) with respect to the molybdenum film etching rate of the composition of Comparative Example C3.

TABLE 2

| | | | | | | | Molybdenum | Silicon |
|---|---|---|---|---|---|---|---|---|
| | | | | | | | film | oxide |
| | | | | | | | etching | film |
| | | | | | | | rate | etching |
| | Oxidizing | | | | | | (relative | rate |
| | agent | Acid | | Etching controller | | pH | value, %) | (Å/min) |
| Example 5 | Hydrogen | Phosphoric | Acetic | 1 | P1 | −0.499 | 28 | <1 |
| | peroxide | acid | acid | (0.1 wt %) | (0.5 wt %) | | | |
| | (0.5 wt %) | (60 wt %) | (10 wt %) | | | | | |
| Comparative | Hydrogen | Phosphoric | Acetic | — | | −0.595 | 100 | <1 |
| Example | peroxide | acid | acid | | | | | |
| C3 | (0.5 wt %) | (60 wt %) | (10 wt %) | | | | | |

From Table 2, it can be confirmed that the composition Comparative Example C3, which does not include an etching controller, excessively etches the molybdenum film, whereas the composition of Example 5 can simultaneously etch bath the titanium nitride-containing film and the molybdenum film at a more appropriate etching ratio without substantially damaging the silicon oxide film and without excessively etching the molybdenum film, and thus can be usefully used for more uniform etching of metal-containing films having various compositions.

The composition according to embodiments facilitates control of the etching rate for various metal-containing films, and thus can be effectively used in various treatment processes for the metal-containing film, such as etching, cleaning, and polishing processes. By processing the metal-containing film using the composition, higher-quality electronic devices and/or semiconductor devices can be manufactured.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of treating a metal-containing film, comprising:
preparing a substrate including the metal-containing film, the metal-containing film including a first region and a second region; and
contacting the metal-containing film with a composition;
wherein the first region and the second region independently comprise titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or any combination thereof,
wherein a material included in the first region is different from a material included in the second region,
wherein the composition comprises an oxidizing agent, an acid and an etching controller,
wherein the etching controller comprises at least one of a compound represented by Formula 1 and a polymer comprising a repeating unit represented by Formula 2, 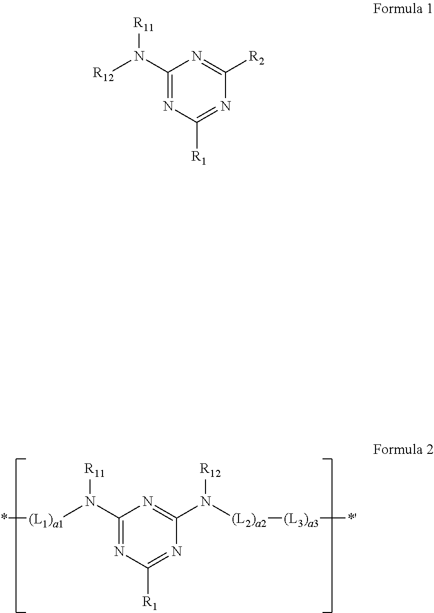
wherein, in Formulae 1 and 2,
R₁ and R₂ are each independently:
hydrogen, a halogen atom, *—OH, *—SH, or *—C(═O)OH;
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof; or 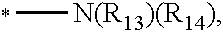
R₁₁ to R₁₄ are each independently:
hydrogen, a halogen atom, *—OH, *—SH, or *—C(═O)OH; or
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
L₁ to L₃ are each independently:
a single bond, O, or S; or
a C₁-C₃₀ alkylene group, a C₂-C₃₀ alkenylene group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
a1 to a3 are each independently an integer from 1 to 30, and
* and *′ each indicate a binding site to a neighboring atom.

2. The method of claim 1,
wherein the first region comprises titanium (Ti), indium (In), aluminum (Al), lanthanum (La), scandium (Sc), gallium (Ga), or any combination thereof, and
the second region comprises tungsten (W), molybdenum (Mo), ruthenium (Ru), or any combination thereof.

3. The method of claim 1,
wherein the first region comprises a metal nitride, a metal oxynitride, or any combination thereof, and
the second region comprises a conductive metal.

4. The method of claim 1,
wherein the first region comprises a titanium nitride, a titanium oxynitride, or any combination thereof and each of the titanium nitride and the titanium oxynitride optionally further comprises indium (In), aluminum (Al), lanthanum (La), scandium (Sc), gallium (Ga), silicon (Si), or any combination thereof.

5. The method of claim 1,
wherein an etching area ratio, which is a ratio obtained by dividing a first area of the first region exposed for contact with the composition by a second area of the second region exposed for contact with the composition, is in a range of about 0.05 to about 1.0.

6. The method of claim 1, wherein
the acid includes an inorganic acid, or
the acid includes an organic acid, or
the acid includes the inorganic acid and the organic acid, and
wherein the acid includes a phosphoric acid and the acid includes a carboxylic acid.

7. The method of claim 1, wherein
the compound represented by Formula 1 is a compound represented by Formula 1A, and
the repeating unit represented by Formula 2 is a repeating unit represented by Formula 2A: 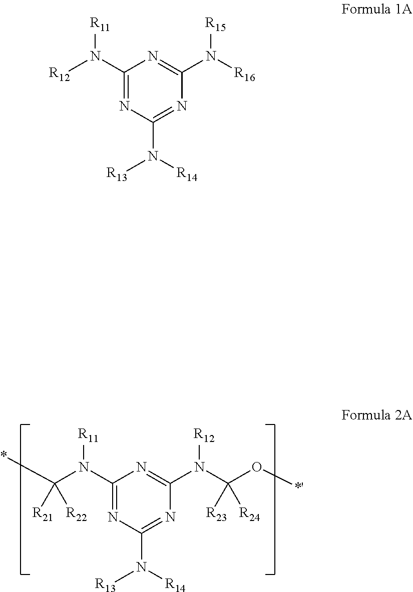
wherein, in Formulae 1A and 2A,
R₁₁ to R₁₄ are each the same as described in Formulae 1 and 2,
R₁₅ and R₁₆ are each as described in connection with R₁₃ in Formulae 1 and 2,
R₂₁ to R₂₄ are each independently hydrogen, a halogen atom, *—OH, *—SH, *—C(═O)OH, a C₁-C₃₀ alkyl group, a C₂-C₃₀ alkenyl group, a C₁-C₃₀ alkoxy group, or a C₁-C₃₀ alkylthio group, and
* and *′ each indicate a binding site to a neighboring atom.

8. The method of claim 1, wherein
an amount of the etching controller is about 0.01 wt % to about 5 wt % based on 100 wt % of the composition.

9. A method of manufacturing an electronic device including a transistor,
the transistor comprising
a channel,
a source and a drain spaced apart from each other and electrically connected to the channel,
a gate electrode, and
a gate insulating film between the gate electrode and the channel, and
the method comprising:
providing a barrier layer comprising a metal nitride, a metal oxynitride, or any combination thereof;
providing a conductive layer including a conductive metal; and
forming the gate electrode by bringing the barrier layer and the conductive layer into contact with a composition to etch a portion of the barrier layer and a portion of the conductive layer;
wherein the composition comprises an oxidizing agent, an acid and an etching controller, and
wherein the etching controller comprises at least one of a compound represented by Formula 1 and a polymer comprising a repeating unit represented by Formula 2: 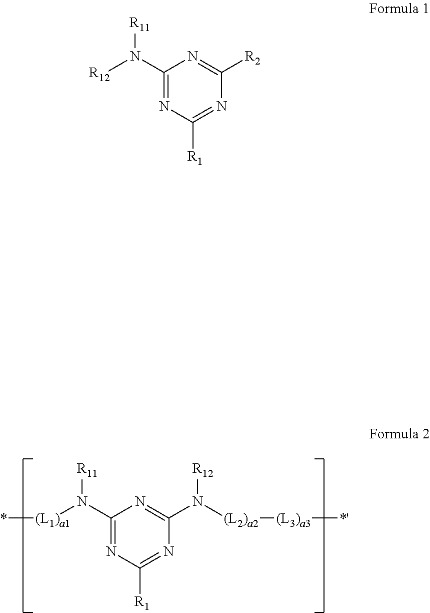
wherein, in Formulae 1 and 2,
R₁ and R₂ are each independently:
hydrogen, a halogen atom, *—OH, *—SH, or *—C(═O)OH;
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof; or 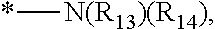
R₁₁ to R₁₄ are each independently:
hydrogen, a halogen atom, *—OH, *—SH, or *—C(═O)OH; or
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
L₁ to L₃ are each independently:
a single bond, O, or S; or
a C₁-C₃₀ alkylene group, a C₂-C₃₀ alkenylene group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof, a1 to a3 are each independently an integer from 1 to 30, and
* and *′ each indicate a binding site to a neighboring atom.

10. The method of claim 9,
wherein the barrier layer comprises a titanium nitride, a titanium oxynitride, or any combination thereof,
each of the titanium nitride and the titanium oxynitride optionally further comprises indium (In), aluminum (Al), lanthanum (La), scandium (Sc), gallium (Ga), silicon (Si), or any combination thereof, and
the conductive layer comprises tungsten (W), molybdenum (Mo), ruthenium (Ru), or any combination thereof.

11. The method of claim 9, further comprising:
after the forming of the gate electrode by bringing the barrier layer and the conductive layer into contact with the composition to etch the portion of the barrier layer and the portion of the conductive layer, such that an etched barrier layer and an etched conductive layer are formed, providing an insulating layer on a surface of the etched barrier layer and a surface of the etched conductive layer.

12. A composition comprising:
an oxidizing agent;
an acid; and
an etching controller, wherein
the etching controller comprises at least one of a compound represented by Formula 1 and a polymer comprising a repeating unit represented by Formula 2, 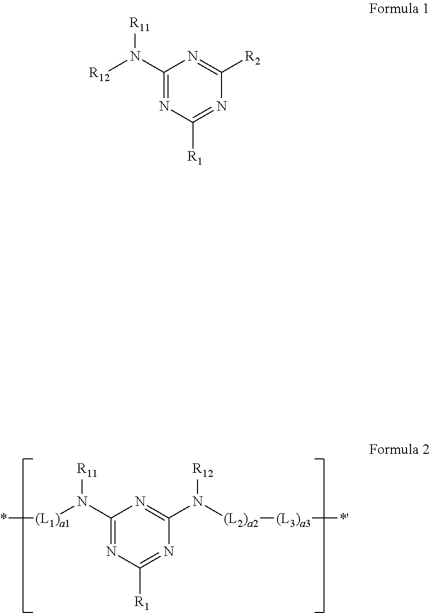
wherein, in Formulae 1 and 2,
R₁ and R₂ are each independently:
hydrogen, a halogen atom, *—OH, *—SH, or *—C(═O)OH;
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof; or 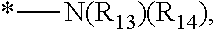
R₁₁ to R₁₄ are each independently:
hydrogen, a halogen atom, *—OH, *—SH, or *—C(═O)OH; or
a C₁-C₃₀ alkyl group, a C₂-C₃₀ alkenyl group, a C₁-C₃₀ alkoxy group, a C₁-C₃₀ alkylthio group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
L₁ to L₃ are each independently:
a single bond, O, or S; or
a C₁-C₃₀ alkylene group, a C₂-C₃₀ alkenylene group, a C₃-C₃₀ carbocyclic group, or a C₁-C₃₀ heterocyclic group, each unsubstituted or substituted with a halogen atom, *—OH, *—SH, *—C(═O)OH, a C₁-C₃₀ alkyl group, a C₂-C₃₀ alkenyl group, a C₁-C₃₀ alkoxy group, a C₁-C₃₀ alkylthio group, or any combination thereof,
a1 to a3 are each independently an integer from 1 to 30, and
* and *′ each indicate a binding site to a neighboring atom.

13. The composition of claim 12, wherein
the oxidizing agent comprises hydrogen peroxide.

14. The composition of claim 12, wherein
an amount of the oxidizing agent is about 0.001 wt % to about 10 wt % based on 100 wt % of the composition.

15. The composition of claim 12, wherein
the acid includes an inorganic acid, or
the acid includes an organic acid, or
the acid includes the inorganic acid and the organic acid, and wherein the acid includes a phosphoric acid and the acid includes a carboxylic acid.

16. The composition of claim 12, wherein
an amount of the acid is about 10 wt % to about 90 wt % based on 100 wt % of the composition.

17. The composition of claim 12, wherein
R₁ and R₂ in Formulae 1 and 2 are each independently: 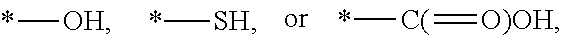
a C₁-C₁₀ alkyl group, a C₁-C₁₀ alkoxy group, or a C₁-C₁₀ alkylthio group, each unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof; or 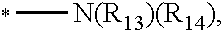
R₁₁ to R₁₄ in Formulae 1 and 2 are each independently:
hydrogen, *—OH, *—SH, or *—C(═O)OH; or
a C₁-C₁₀ alkyl group, a C₁-C₁₀ alkoxy group, or a C₁-C₁₀ alkylthio group, each unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof.

18. The composition of claim 12, wherein
L₁ to L₃ in Formula 2 are each independently:
O or S; or
a C₁-C₁₀ alkylene group which is unsubstituted or substituted with *—OH, *—SH, *—C(═O)OH, a C₁-C₁₀ alkyl group, a C₁-C₁₀ alkoxy group, a C₁-C₁₀ alkylthio group, or any combination thereof, and
a1 to a3 are each independently an integer from 1 to 5.

19. The composition of claim 12, wherein
the compound represented by Formula 1 is a compound represented by Formula 1A, and
the repeating unit represented by Formula 2 is a repeating unit represented by Formula 2A: 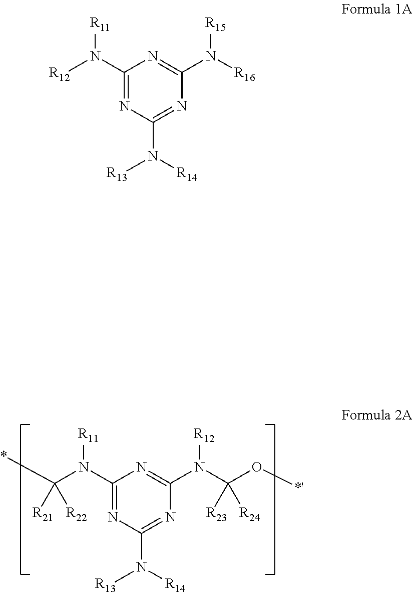
wherein, in Formulae 1A and 2A,
R₁₁ to R₁₄ are each the same as described in Formulae 1 and 2,
R₁₅ and R₁₆ are each as described in connection with R₁₃ in Formulae 1 and 2,
R₂₁ to R₂₄ are each independently hydrogen, a halogen atom, *—OH, *—SH, *—C(═O)OH, a C₁-C₃₀ alkyl group, a C₂-C₃₀ alkenyl group, a C₁-C₃₀ alkoxy group, or a C₁-C₃₀ alkylthio group, and
* and *′ each indicate a binding site to a neighboring atom.

20. The composition of claim 12, wherein
an amount of the etching controller is about 0.01 wt % to about 5 wt % based on 100 wt % of the composition.
